(19) United States
(12) Patent Application Publication
(10) Pub. No.: US 2002/0064930 A1
(43) Pub. Date: May 30, 2002

(54) Method for forming a solder bump, and process for fabricating a semiconductor device

(76) Inventor: Natsuya Ishikawa, Kanagawa (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 09/902,151

(22) Filed: Jul. 10, 2001

(30) Foreign Application Priority Data
Jul. 12, 2000 (JP) P2000-211861

(51) Int. Cl. H01L 21/44

(52) U.S. Cl. 438/612; 438/614

(57) ABSTRACT

Providing a method for forming a solder bump and a process for fabricating a semiconductor device, which can form an optimum solder bump for IC chips at a low cost. An opening portion is formed in an inexpensive photoresist having a low heat resistance formed on a wafer, and only a solder paste filling the opening portion is partly heated by a laser beam to form a solder bump. Thus, there can be provided a method for forming a solder bump, which is advantageous not only in that the predetermined amount of a solder bump can be formed in the opening portion formed with a high accuracy without dispersion, but also in that the cost can be lowered because of the use of an inexpensive photoresist.

### CROSS REFERENCES TO RELATED APPLICATIONS

The present document is based on Japanese Priority Document JP 2000-211861, filed in the Japanese Patent Office on Jul. 12, 2000, the contents of which being herein incorporated by reference.

### BACKGROUND OF THE INVENTION

1. Field of the Invention

The present invention relates to a method for forming a solder bump and a process for fabricating a semiconductor device, which can form an optimum solder bump for, for example, semiconductor devices, especially electrodes of flip-chip-type integrated circuits.

2. Related Art

A flip chip mounting known as a method for high density mounting is a mounting method in which an integrated circuit (hereinafter, frequently referred to simply as “IC”) chip is connected to a circuit substrate by a protruding electrode called a bump, which is formed in the electrode of the IC chip. In such a case, as a method for forming a spherical solder bump in the electrode of the IC chip, a solder vapor deposition process, an electroplating process, or a printing process is employed.

However, the solder vapor deposition process requires a long time for the vapor deposition of a solder, causing the cost to be increased, and especially in the vapor deposition process using a metal mask, heat generated during the vapor deposition causes the metal mask to suffer extension and lifting, so that it is difficult to form a bump at a fine pitch. Further, a lift-off method using a photoresist has a problem in that it is difficult to lift off a solder film having a large thickness.

The solder electroplating process has problems in that: the composition of the grown solder is dispersed; a wiring for electroplating must be formed and a step for removal of the wiring is needed after forming the bump, and hence, an increase in the number of the steps causes the cost to be increased; and the bump formed is likely to suffer dispersion in height due to the dispersion of the plating growth.

On the other hand, differing from the above-mentioned vapor deposition process and electroplating process, the printing process is a process in which a solder paste is transferred using a screen mask, followed by heat-melting, thus forming a solder bump. Therefore, the printing process can form a large amount of solder bumps in a short time, namely, form solder bumps at a low cost, as compared to the vapor deposition process and the electroplating process. However, the printing process poses the following problem. In accordance with the trend towards finer pitch for bumps, the opening form in a screen mask is further reduced in size, and, as a result, the aspect ratio of the opening in the screen mask is increased. Therefore, all the solder paste supplied into the opening portion is not transferred to the electrode portion of an IC but left in the screen mask, and thus, the transfer efficiency of the solder is lowered and the transfer is dispersed, so that the dispersion of the height of the bump formed becomes disadvantageously large. Thus, the formation of solder bumps at a fine pitch is difficult in the printing process, as compared to that in each of the vapor deposition process and the electroplating process.

For solving the above-mentioned problem, the present applicant has proposed a method for forming a solder bump at a fine pitch using the printing process, i.e., a method described in Unexamined Japanese Patent Application Laid-Open Specification No.7-321113 (hereinafter, referred to as “method of the earlier application”).

In the method of the earlier application, using no screen mask but using a heat resistant resist, an opening portion is formed in the portion where a solder bump is to be formed, and the resultant opening portion is filled with a solder paste and heat-melted in a state such that the solder paste is in the opening portion. Therefore, a step for transfer of the solder using a screen mask can be omitted, and hence, there occurs no dispersion of the bump height due to the lowering of the transfer efficiency caused when the above step for transfer of the solder is performed, so that the formation of bumps at a fine pitch can be achieved, as compared to that achieved by the conventional printing process.

Thus, the earlier application has optimum features such that the use of the printing process enables a large amount of solder bumps to be formed at a low cost, and further, the use of a heat resistant photoresist enables solder bumps to be formed at a fine pitch, but it has been found that the method of the earlier application needs to be further improved.

Specifically, as shown in FIG. 11, when mounting is conducted in a state such that a heat resistant photoresist 5 is left on an IC, the height of a solder bump 10 is lowered due to the presence of a heat resistant photoresist 5. When an IC 1 with the solder bump having the heat resistant photoresist 5 produced by the above method is subjected to flip chip mounting, for enhancing the reliability for mounting, the gap width of the region of an encapsulation resin 11 to be encapsulated between the IC 1 with bump and a printed circuit board 12 is reduced, so that the encapsulation properties of the encapsulation resin 11 become poor and a phenomenon such that the encapsulation efficiency is lowered is likely to occur. The more marked the phenomenon, the finer the pitch for the solder bump, i.e., the lower the solder bump height.

However, actually, as the heat resistant photoresist, polyimide, PBO (polyparaphenylenebenzobisoxazole), or BCB (benzocyclobutene) is generally used, and such a photoresist is difficult to be removed by ashing and is therefore left as it is. Even if the above photoresist can be removed, the photoresist has a disadvantage in that the material therefor is expensive. Therefore, in any case where the heat resistant photoresist is left or removed, there is a problem in that it is difficult to lower the cost due to the use of the expensive heat resistant photoresist.

### SUMMARY OF THE INVENTION

Therefore, it is an object of the present invention to provide a method for forming a solder bump and a process for fabricating a semiconductor device, which can form an optimum solder bump at a low cost.

Specifically, the present invention is directed to a method for forming a solder bump (hereinafter, referred to as “solder bump formation method according to a preferred embodiment of the present invention”), which includes the steps of forming a photoresist on a semiconductor wafer, subjecting the photoresist to exposure through a predetermined pattern, subjecting the resultant photoresist to development to form an opening portion in the photo resist, supplying a solder material into the opening portion, and heat-melting only the solder material in the opening portion so that the solder material becomes in a spherical shape to form a solder bump. In such method, only the solder material supplied into the opening portion is heated, and therefore, as a mask, a screen mask is not used but a photo resist is used, and an opening can be formed with a high opening accuracy, and the opening portion where a solder bump is to be formed can be filled with the predetermined amount of a solder material without dispersion, thus making it possible to form a solder bump having a predetermined bump height and form. In addition, only the solder material supplied into the opening portion is heated, and therefore, only the solder material in the opening portion is melted and the surface tension of the liquefied solder material enables a spherical solder bump to be formed in the opening portion. Further, portions other than the opening portion are not heated, and thus, an inexpensive photo resist having a low heat resistance can be used.

In the solder bump formation method according to the preferred embodiment of the present invention, as a mask, a screen mask is not used but a photoresist is used to determine the form of an opening portion. Therefore, an opening can be formed with a high opening accuracy, and the opening portion where a solder bump is to be formed can be filled with the predetermined amount of a solder material without dispersion, thus making it possible to form a solder bump having the predetermined bump height and form. In addition, only the solder material supplied into the opening portion is heated, and therefore, only the solder material in the opening portion is melted and the surface tension of the liquefied solder material enables a spherical solder bump to be formed in the opening portion. Further, portions other than the opening portion are not heated, and thus, an inexpensive photoresist having a low heat resistance can be used.

Further, the preferred embodiment of the present invention is directed to a process for fabricating a semiconductor device (hereinafter, referred to as “semiconductor device fabrication process according to a preferred embodiment of the present invention”), which includes the steps of forming a photoresist on a semiconductor wafer, subjecting the photoresist to exposure through a predetermined pattern, subjecting the resultant photoresist to development to form an opening portion in the photoresist, supplying a solder material into the opening portion, and heat-melting only the solder material in the opening portion so that the solder material becomes in a spherical shape to form a solder bump.

In the semiconductor device fabrication process according to the preferred embodiment of the present invention, a solder bump is formed in accordance with the above-mentioned solder bump formation method. Therefore, there can be provided a process for fabricating a semiconductor device having a solder bump, which exhibits the similar effect to that of the solder bump, formed by the above method.

### BRIEF DESCRIPTION OF THE DRAWINGS

The foregoing and other objects, features and advantages of the present invention will be apparent to those skilled in the art from the following description of the presently preferred exemplary embodiments of the invention taken in connection with the accompanying drawings, in which:

FIG. 1 is a diagrammatic cross-sectional view showing the state of partly heating by a laser beam according to a preferred embodiment of the present invention;

FIG. 2 is a diagrammatic cross-sectional view showing the state of partly heating by a visible light according to a preferred embodiment of the present invention;

FIGS. 3A and 3B are diagrammatic cross-sectional views of a semiconductor device, showing one step for the solder bump formation according to a preferred embodiment of the present invention;

FIG. 4 is a diagrammatic cross-sectional view of a semiconductor device, showing another step for the solder bump formation according to a preferred embodiment of the present invention;

FIG. 5 is a diagrammatic cross-sectional view of a semiconductor device, showing another step for the solder bump formation according to a preferred embodiment of the present invention;

FIG. 6 is a diagrammatic cross-sectional view of a semiconductor device, showing another step for the solder bump formation according to a preferred embodiment of the present invention;

FIG. 7 is a diagrammatic cross-sectional view of a semiconductor device, showing still another step for the solder bump formation according to a preferred embodiment of the present invention;

FIG. 8A and FIG. 8B are diagrammatic cross-sectional views showing the state of mounting for a semiconductor device according to a preferred embodiment of the present invention;

FIG. 9 is a diagrammatic cross-sectional view showing the state of a semiconductor device before mounting according to a preferred embodiment of the present invention;

FIG. 10 is a diagrammatic cross-sectional view showing the state of another mounting for a semiconductor device according to a preferred embodiment of the present invention; and

FIG. 11 is a diagrammatic cross-sectional view showing the state of a semiconductor device after mounting according to a method of the earlier application.

### DETAILED DESCRIPTION OF THE PREFERRED EMBODIMENTS

In the above-mentioned solder bump formation method and semiconductor device fabrication process of the present invention, it is desired that the opening portion is filled with a solder paste as the solder material and the solder paste is heat-melted so that it turns to a spherical shape.

In this case, it is desired that the heat melting is conducted by radiation of a laser beam.

Alternatively, the heat melting can be conducted by radiation of visible light.

In addition, after formation of the solder bump, the method may further comprise a step of removing the photoresist.

It is desired that, as the photoresist, a novolak resin material is used.

Further, it is desired that the process further comprises a step of mounting on a circuit substrate a semiconductor chip cut out from the semiconductor wafer through the solder bump.

Hereinbelow, the preferred embodiments of the present invention will be described in more detail with reference to the accompanying drawings.

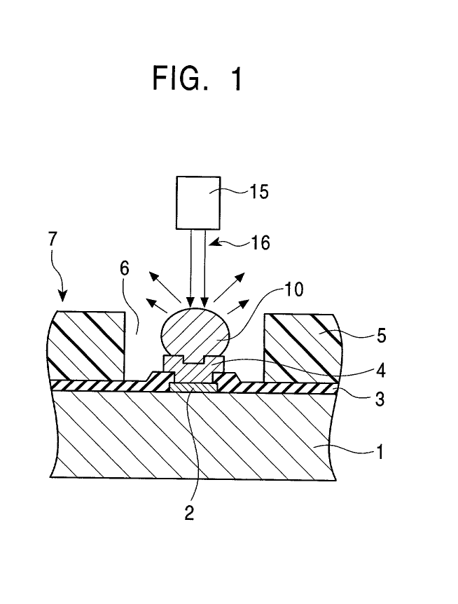

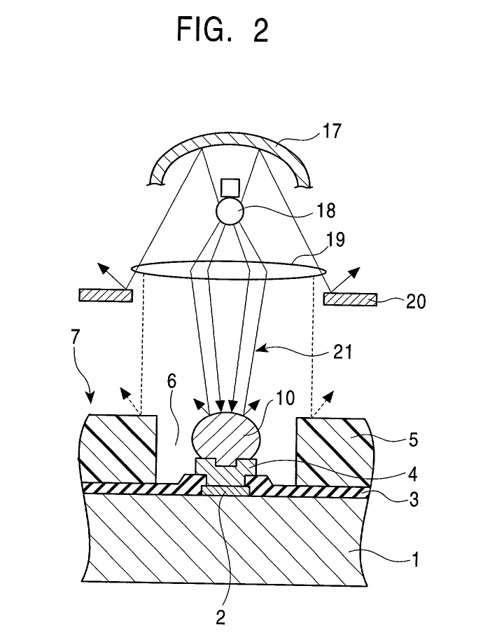

The present embodiment enables the bump arrangement at a fine pitch, which cannot be achieved by a printing process, while securing the low cost which is an advantage of the printing process, and does not use an expensive heat resistant photoresist but an inexpensive novolak resin photoresist. As a method for heating, a laser beam is used as shown in FIG. 1 or a visible light is used as shown in FIG. 2 to heat-melt a solder paste to minimize a thermal damage of the photo resist, thus forming a solder bump at a low cost at a fine pitch (the pitch is 100 to 150 μm, whereas the conventional pitch is 200 μm).

Specifically, in the preferred embodiment of the present invention, a solder bump is formed as follows. By the below-mentioned production process, a barrier metal layer 4 is formed on an electrode pad 2 of a wafer 1, and an opening portion 6 is formed in a photoresist layer 5 on a passivation film 3, and a solder paste 9 supplied into the opening portion 6 (see FIG. 7) is partly heat-melted by a laser beam 16 emitted from a laser 15 as shown in FIG. 1, so that the surface tension of the liquefied solder paste 9 enables a spherical solder bump 10 to be formed.

Alternatively, as shown in FIG. 2, a solder paste 9 supplied by the above production process can be partly heated by a visible light 21 emitted from, for example, a halogen lamp 18 through a lends 19 and a reflector 17 (numeral 20 in the figure denotes a slit) to form a similar spherical solder bump 10.

A novolak resin photo resist generally produced has a heat resistance temperature of about 100° C., and is therefore changed in shape in about 2 to 3 minutes, and, at about 150° C., the photo resist suffers change in properties in addition to the change in shape. Further, generally, in a reflow apparatus for heating a solder paste, the whole of the wafer 1 is heated. In the production of a SnPb eutectic bump, when the peak temperature is 240° C. and the heating temperature is about 150° C., the wafer is heated for 1 to 3 minutes, and, when the heating temperature is about 100° C., the wafer is heated for about 5 to 7 minutes. Therefore, when the wafer having thereon a novolak resin photoresist is heated in a reflow apparatus under the above heating conditions, the novolak resin photoresist suffers change in shape and properties.

However, in the present preferred embodiment of the invention, even when the above novolak resin photoresist is used, only the solder paste 9 is heated using a laser beam 16 or a visible light 21 for a time as short as about 0.1 to 1 second per bump, and further, the solder is melted by partly heating and only the solder paste 9 is heat-melted, so that a spherical solder bump 10 can be formed in a short time.

As mentioned above, only the solder paste 9 is partly heated, and thus, almost no heat is transmitted to the photoresist 5 present in the periphery of the solder paste 9 during heating. Therefore, the thermal damage of the photoresist 5 can be minimized, and the photoresist can be easily removed by the subsequent washing with an organic solvent or ashing using oxygen plasma.

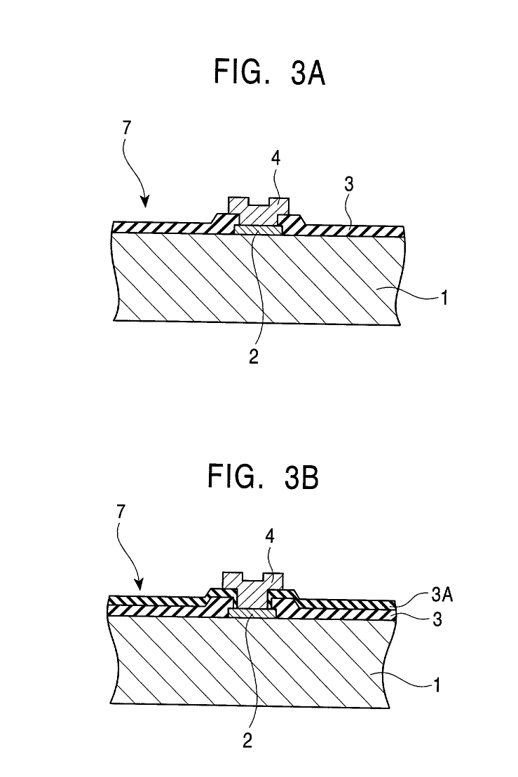

Next, a method for forming a solder bump according to a preferred embodiment of the present embodiment is shown in FIG. 3 to FIG. 7.

FIG. 3A shows the state of a semiconductor wafer 1 such that a barrier metal layer 4 is formed on an electrode pad 2 which is part of a semiconductor chip region 7. The barrier metal layer 4 is formed by a conventionally known process, such as an electroplating process, a vapor deposition process, a sputtering process, or an electroless plating process, or a combination of these processes. A passivation film 3 is formed from a silicon nitride film or a silicon oxide film by a conventionally known wafer process.

In addition, as shown in FIG. 3B, for reducing the area of the exposed electrode pad 2, an auxiliary passivation film 3A may be further formed from polyimide, for example.

As examples of sizes of the above parts, there can be mentioned the following. For example, when the pad pitch of the electrode pad 2 is 120 μm, the size of the electrode pad 2 is 100 μm square, the thickness of the passivation film 3 is 1.5 μm, the size of the opening portion is 95 μm square, the thickness of the auxiliary passivation film 3A is 2 μm, the size of the opening portion is 60 μmφ and a representative combination of the construction of the barrier metal layer 4 and the thickness thereof is such that 100 nm-thick Cr, 2 μm-thick Cu as an adhesive layer, and 100 nm-thick Au as a protecting film for Cu are stacked in this order on the Al electrode pad 2. In addition, the diameter of the barrier metal layer 4 is 70 μmφ. Further, the construction of the barrier metal layer 4 can be either Cr, Ni, and Cu from bottom or Cr, Ni, and Au from bottom.

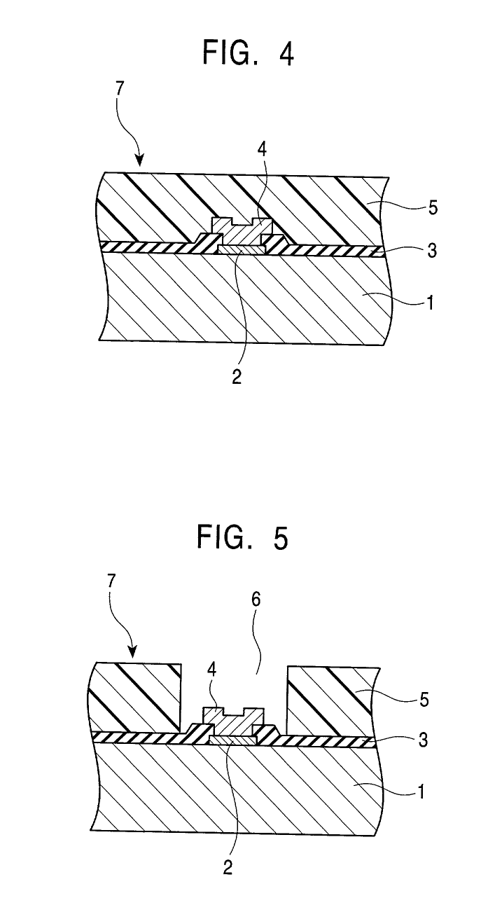

Then, as shown in FIG. 4, a photoresist is applied to the upper surface after the step shown in FIG. 3 to form a photoresist layer 5. The application may be conducted by a spin coating process, for example.

As a material for the photoresist layer 5, any positive photoresist and negative photoresist may be used as long as they have such a patterning accuracy that the predetermined opening form can be obtained. In the present embodiment, a novolak resin resist which is a positive photoresist and mass-produced (PMER-900, manufactured and sold by TOKYO OHKA KOGYO CO., LTD., Japan) is used, and deposited so that the thickness of the film applied becomes about 20 μm.

Then, as shown in FIG. 5, an opening portion 6 is formed. The opening portion 6 can be formed with a high accuracy by a method in which the photoresist layer 5 is masked and exposed to ultraviolet radiation, for example, and then, subjected to development by an organic solvent. The form of the opening portion 6 may be any of a circular form, an elliptical form, a rectangular form, and other forms, and the filling amount of the solder paste can be controlled by changing the area of the opening portion 6 and the thickness of the resist 5.

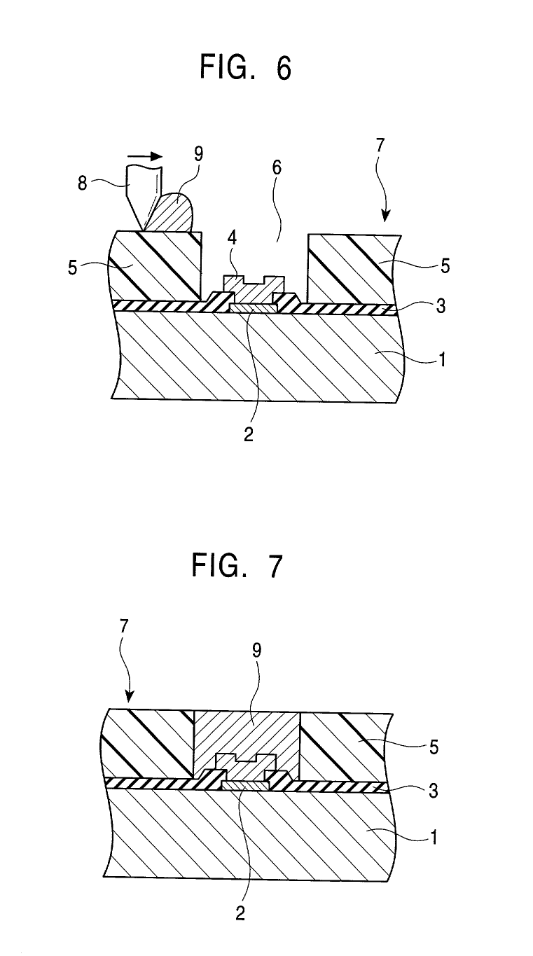

Then, as shown in FIG. 6, a solder paste 9 is supplied into the opening portion 6 formed in the photoresist layer 5 by squeegeeing using a squeegee 8. The solder paste 9 used in the present embodiment has a composition such that the tin:lead ratio is 63:37 (% by weight), and the particle diameter of the solder particles in the solder paste used is 5 to 15 μm By the above-mentioned squeegeeing using the squeegee 8, as shown in FIG. 7, the opening portion 6 is filled with the solder paste 9, and the solder paste is not supplied in portions other than the opening portion 6.

Then, as already mentioned in connection with FIG. 1, the solder paste 9 supplied in the opening portion 6 is irradiated with a laser beam 16 having a beam diameter reduced from a laser 15. In the present embodiment, the beam diameter of the laser beam emitted is reduced to about 30 μmφ.

As the laser 15, a YAG laser is used, and the wavelength of the laser beam 16 is 1,064 nm and the output is 5 J. Thus, the solder paste 9 is melted in an irradiation time as short as about 0.3 second per bump to form a spherical solder bump 10. Further, the solder paste 9 is irradiated with the laser beam 16 while scanning the laser beam, and the solder paste 9 in the predetermined position is successively melted (wet back), so that all the solder bumps 10 formed are in a spherical shape.

In addition, as already mentioned in connection with FIG. 2, when the solder paste 9 supplied in the opening portion 6 is irradiated with a visible light 21 having a beam diameter reduced, a similar solder bump 10 can be formed. In the present embodiment, the beam diameter of the visible light emitted is reduced to about 200 μmφ. As a visible light source, a halogen lamp 18 at 1.0 kW is used, and the light is condensed by a reflector 17 and a lens 19 as well as a slit 20, and thus, the solder paste 9 is melted in an irradiation time as short as about 1 second, so that the spherical solder bump 10 can be formed.

When halogen lamp is used as a light source, it is difficult to reduce the beam diameter to an even smaller size, but, even when the beam width is larger than the diameter of the opening portion 6, the temperature of the center portion of the light flux becomes high and the temperature of the outer periphery portion of the light flux is lower than that of the center portion. Therefore, even when the photoresist layer 5 is irradiated with the light from a halogen lamp, the thermal damage of the photoresist layer 5 can be minimized.

As mentioned above, in the preferred embodiment of the present invention, the barrier metal 4 is formed on the electrode 2 of the semiconductor wafer 1 having formed thereon an IC (integrate circuit) and the like, and then, the photoresist layer 5 is formed from a photoresist generally used and the opening portion 6 is formed in the photoresist 5, and the opening portion 6 is filled with the solder paste 9 by means of the squeegee 8, and only the solder paste 9 is heated by a laser beam or a visible light, so that only the solder paste 9 can be melted while causing almost no increase in the temperature of the photoresist 5 on the periphery of the solder paste.

In addition, the opening form is determined using a photoresist, and therefore the opening portion 6 can be formed with a high accuracy and the opening portion 6 can be filled with the predetermined amount of the solder paste 9 without dispersion, so that a solder bump having a predetermined height and form can be formed. Therefore, not only can the formation of the solder bump 10 at a fine pitch be achieved, but also the solder bump 10 can be prepared at a low cost because of the use of an inexpensive photoresist.

In the preferred embodiment of the present invention, the photo resist 5 can be left without being removed, and, when the photoresist 5 is removed, it can be removed either by washing with an organic solvent, such as DMSO (dimethyl sulfoxide) or NMP (N-methylpyrrolidone), or by ashing using oxygen plasma. In any case, since the solder paste portion is partly heated by irradiation with a laser beam or a visible light to minimize the thermal damage of the photoresist 5 during the melting of the bump, the photoresist 5 suffers substantially no change in properties, so that the photoresist can be easily removed. On the other hand, for example, when the photoresist 5 is left without being removed, a heat resistant material can be used in the photoresist 5.

Finally, for removing the flux residue retaining on the surface of the spherical solder bump 10, washing is performed using a commercially available glycol ether or hydrocarbon flux cleaning agent, thus completing the formation of the spherical solder bump 10.

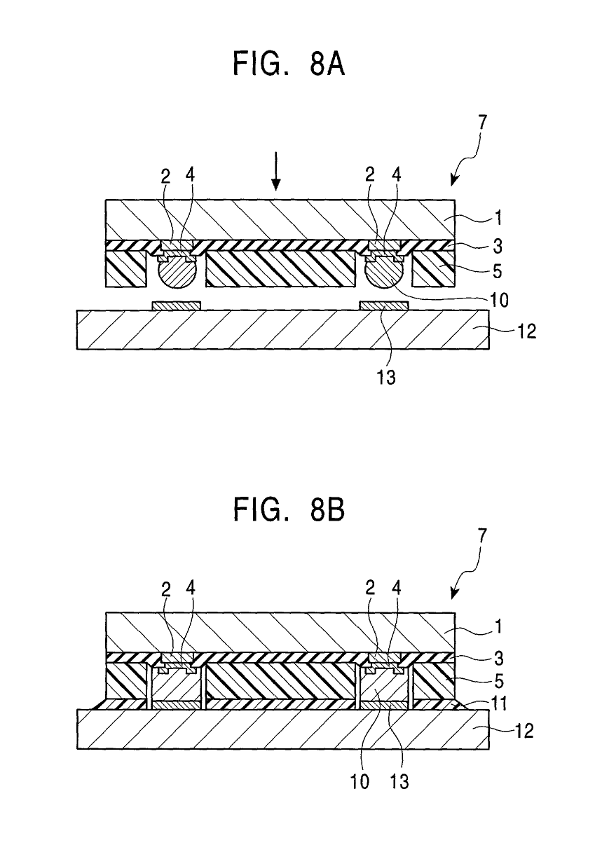

The mounting of an IC chip 7 having the photoresist layer 5 left thereon according to the preferred embodiment of the present invention on a printed circuit board 12 is shown in FIGS. 8A and 8B.

Specifically, as shown in FIG. 8A, an IC chip 7 is faced down to a printed circuit board 12 and they are subjected to reflow, so that, as shown in FIG. 8B, a solder bump 10 is welded onto an electrode pad 13 of the printed circuit board 12 and the printed circuit board 12 is connected to the IC chip 7. An encapsulation resin 11 is encapsulated between the photoresist layer 5 of the IC chip 7 and the printed circuit board 12, thus completing the mounting of the IC chip 7. This case is similar to the earlier application mentioned with reference to FIG. 11 in a point that the photoresist 5 is left, but, in this case, the photoresist 5 is formed from an inexpensive material, thus making it possible to realize a reduction in the cost therefor.

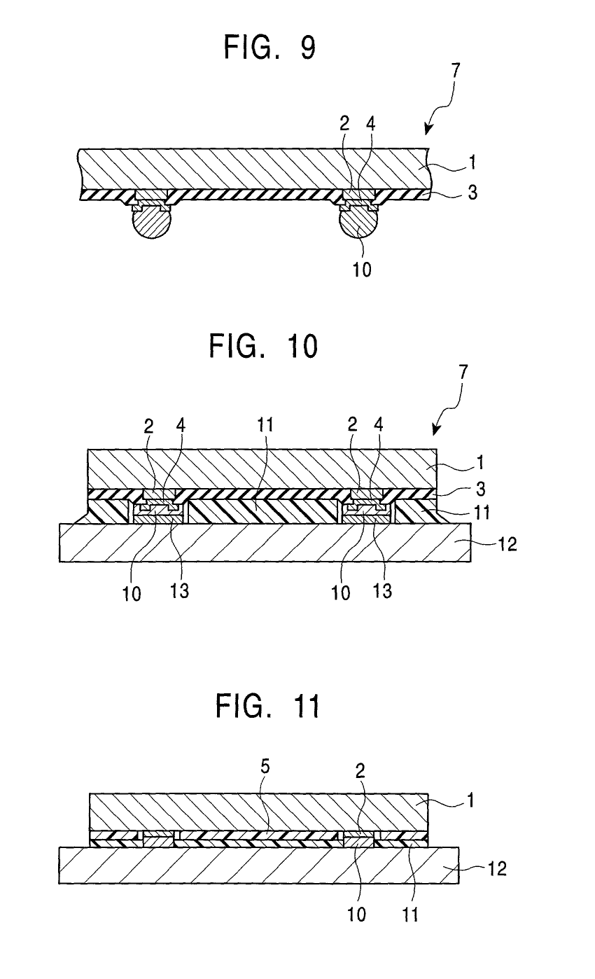

FIG. 9 shows the state in which the photoresist 5 is removed by washing with an organic solvent as mentioned above according to the present embodiment.

FIG. 10 shows the state of mounting of the IC chip 7, in which the photoresist 5 is removed as mentioned above, on the printed circuit board 12 having disposed therebetween the encapsulation resin 11. As shown in the figure, in this case, the photoresist 5 is not present, and therefore, a satisfactory gap can be secured between the IC chip 7 and the printed circuit board 12 to increase the thickness of the layer of the encapsulation resin 11, so that the adhesion between the IC chip 7 and the printed circuit board 12 can be improved.

Thus, by removing the photoresist 5, in the mounting of the IC chip on the printed circuit board 12, the gap width for the encapsulation resin 11 to be encapsulated between the IC chip 7 and the printed circuit board 12 can be increased, so that the encapsulation properties of the encapsulation resin can be improved. Therefore, even when the bump size is reduced and the bump strength is lowered, the improvement in the encapsulation properties of the encapsulation resin enables the formation of solder bumps at a fine pitch to be easily realized.

In each of the above cases, according to the preferred embodiment of the present invention, the opening form is determined using the photoresist 5, and therefore the opening portion 6 can be formed with high accuracy, and the predetermined amount of the solder paste 9 can be supplied into the opening portion 6 by means of the squeegee 8 without dispersion. Then, only the supplied solder paste 9 is partly heated and melted by irradiation with the laser beam 16 or visible light 21, so that the photoresist 5 on the periphery of the solder paste suffers no thermal damage and the solder bump 10 having the predetermined height and form can be formed from the supplied solder paste 9. In addition, an inexpensive photoresist can be used, and thus, the solder bump 10 can be formed at a low cost, and further, the photoresist 5 can be easily removed after forming the bump and therefore a satisfactory gap can be secured between the IC chip 7 and the printed circuit board 12, so that the encapsulation resin 11 can be securely encapsulated into the gap, thus making it possible to achieve mounting with high reliability (see FIG. 9 and FIG. 10).

Thus, the problems accompanying the prior art that the encapsulation efficiency of the encapsulation resin 11 is lowered and it is difficult to lower the cost due to the use of an expensive heat resistant photoresist can be solved. Further, by realizing an optimum method employing the printing process using a photoresist as a mask, there is no need to form a solder bump by a vapor deposition process and an electroplating process, and thus, the formation of a solder bump is not affected by the problems of these processes.

The above-mentioned preferred embodiments of the present invention can be modified based on the technical concept of the present invention.

For example, the above-mentioned process for forming a solder bump and the structures and materials of the parts therefor in the embodiments can be appropriately changed.

In addition, as the method of partly heating the solder paste, a method similar to those in the embodiments can be appropriately employed.

Further, the application of the method for forming a solder bump in the preferred embodiments is not limited to the semiconductor device. For example, a ball-shape or particulate solder can be allowed to fall into a resist opening portion and subjected to reflow by partly heating by a laser beam and the like to form a solder bump.

As mentioned above, the solder bump formation method of the present invention includes the steps of: forming a photoresist on a semiconductor wafer; subjecting the photoresist to exposure through a predetermined pattern; subjecting the resultant photoresist to development to form an opening portion in the photoresist; supplying a solder material into the opening portion; and heat-melting only the solder material in the opening portion so that the solder material becomes in a spherical shape to form a solder bump.

Finally, the configurations and structures of respective units and portions described specifically with respect to the preferred embodiments of the present invention are only examples of realization of the present invention, so the embodiments thereof should not be construed as to limiting the technical scope of the present invention.

What is claimed is:

1. A method for forming a solder bump, comprising the steps of:
forming a photoresist on a semiconductor wafer;
subjecting said photoresist to exposure through a predetermined pattern;
developing said photo resist in order to forming an opening portion in said photoresist;
supplying a solder material into said opening portion; and
heat melting only said solder material in said opening portion.

2. The method for forming a solder bump according to claim 1, wherein said opening portion is filled with a solder paste as said solder material, and said solder paste is rendered in a spherical shape by heat melting.

3. The method for forming a solder bump according to claim 1, wherein said heat-melting is conducted by radiation of laser beam.

4. The method for forming a solder bump according to claim 1, wherein said heat-melting is conducted by radiation of visible light.

5. The method for forming a solder bump according to claim 1, further comprising a step of removing said photoresist after forming said solder bump.

6. The method for forming a solder bump according to claim 1, wherein a novolak resin material is used as said photo resist.

7. A process for fabricating a semiconductor device, comprising the steps of:
forming a photoresist on a semiconductor wafer;
subjecting said photoresist to exposure through a predetermined pattern;
developing said photo resist in order to form an opening portion in said photoresist;
supplying a solder material into said opening portion; and
heat melting only said solder material in said opening portion.

8. The process for fabricating a semiconductor device according to claim 7, further comprising a step of mounting on a circuit substrate a semiconductor chip cut out from said semiconductor wafer through said solder bump.

9. The process for fabricating a semiconductor device according to claim 7, wherein said opening portion is filled with a solder paste as said solder material, and said solder paste is rendered in a spherical shape by heat-melting.

10. The process for fabricating a semiconductor device according to claim 7, wherein said heat melting is conducted by radiation of laser beam.

11. The process for fabricating a semiconductor device according to claim 7, wherein said heat melting is conducted by radiation of visible light.

12. The process for fabricating a semiconductor device according to claim 7, further comprising a step of removing said photoresist after forming said solder bump.

13. The process for fabricating a semiconductor device according to claim 7, where in a novolak resin material is used as said photoresist.
